(19) United States
(12) Patent Application Publication
(10) Pub. No.: US 2018/0006664 A1
(43) Pub. Date: Jan. 4, 2018

(54) METHODS AND APPARATUS FOR PERFORMING REED-SOLOMON ENCODING BY LAGRANGIAN POLYNOMIAL FITTING

(71) Applicant: Altera Corporation, San Jose, CA (US)

(72) Inventors: Martin Langhammer, Alderbury (GB); Simon Finn, High Wycombe (GB); Sami Mumtaz, London (GB)

(21) Appl. No.: 15/197,433

(22) Filed: Jun. 29, 2016

(51) Int. Cl. H03M 13/15; H03M 13/00

(52) U.S. Cl. CPC H03M 13/1515; H03M 13/611

(57) ABSTRACT

An integrated circuit for implementing a Reed-Solomon encoder circuit is provided. The encoder circuit may include partial syndrome calculation circuitry and matrix multiplication circuitry. The partial syndrome calculation circuitry may receive a message and generate corresponding partial syndromes. The matrix multiplication circuitry may receive the partial syndromes and may compute parity check symbols by multiplying the partial syndromes by predetermined Lagrangian polynomial coefficients. The parity check symbol generation step may be performed in one clock cycle or multiple clock cycles.

### BACKGROUND

The present embodiments relate to Reed-Solomon encoding, and to circuitry for performing such encoding, particularly on an integrated circuit.

Many modern applications encode data prior to transmission of the data on a network using error correcting codes such as Reed-Solomon codes. Such codes are capable of providing powerful error correction capability. For example, a Reed-Solomon code of length n and including n−k check symbols may detect any combination of up to 2t=n−k erroneous symbols and correct any combination of up to t symbols.

Most known techniques for Reed-Solomon encoding are based on polynomial division. The direct application of this method allows for calculation of check symbols, which are sometimes also referred to as parity check symbols, based on the input of one data symbol at a time. With k symbols in a message word, k clock cycles are needed to calculate n−k check symbols. By substitution, it may be possible to calculate the check symbols based on the input of a number of data symbols at once, but the feedback nature of such a calculation means that the critical path grows with each additional parallel input symbol, and the encoder operational frequency is decreased quickly.

Moreover, increasing communications, storage, and processing demands require ever more efficient error correction including Reed-Solomon forward error correction (FEC). Consequently, it is desirable to provide improved mechanisms for implementing error correction.

### SUMMARY

An integrated circuit may configured to implement a Reed-Solomon encoder circuit. The encoder circuit may include partial syndrome calculation circuitry and matrix multiplication circuitry. The partial syndrome calculation circuitry may receive a message and generate corresponding partial syndrome values. The matrix multiplication circuitry may receive the partial syndrome values and generate corresponding parity check symbols.

The matrix multiplication circuitry may include an array of Galois Field multipliers (e.g., constant or variable Galois Field multipliers) for multiplying the partial syndrome values by corresponding predetermined Lagrangian coefficients. The matrix multiplication circuitry may also include Galois Field adders for summing products output from the multipliers.

In one suitable arrangement, the matrix multiplication circuitry may generate the parity symbols in a single clock cycle. In another suitable arrangement, the matrix multiplication circuitry may generate the parity symbols over two or more clock cycles. In such arrangements, the matrix multiplication circuitry may include multiple tables for storing the predetermined Lagrangian coefficients, where the tables can be indexed using a counter to output varying coefficients at each successive clock cycle.

Further features of the invention, its nature and various advantages will be more apparent from the accompanying drawings and following detailed description.

### BRIEF DESCRIPTION OF THE DRAWINGS

FIG. 1 is a diagram of an illustrative integrated circuit in accordance with an embodiment.

FIG. 2 is a diagram of an illustrative Reed-Solomon encoder circuit in accordance with an embodiment.

FIG. 3 is a diagram showing one suitable implementation of a Reed-Solomon encoder circuit that performs matrix multiplication in one clock cycle in accordance with an embodiment.

FIG. 4 is a diagram showing another suitable implementation of a Reed-Solomon encoder circuit that performs matrix multiplication in multiple clock cycles in accordance with an embodiment.

FIG. 5 is a flow chart of illustrative steps for operating a matrix multiplication based Reed-Solomon encoder circuit of the type shown in connection with FIGS. 2-4 in accordance with an embodiment.

### DETAILED DESCRIPTION

The present embodiments provided herein relate to Reed-Solomon encoding and to circuitry for performing such encoding, particularly in an integrated circuit.

Many modern applications encode data prior to transmission of the data on a network. As part of the data encoding, error correcting codes such as Reed-Solomon codes are often included to allow for the detection and/or correction of data signals that were corrupted during the data transmission. Reed-Solomon codes are often used because they provide powerful error correction capabilities.

However, most known techniques for Reed-Solomon encoding are based on polynomial division, and the feedback nature of such techniques implies that the critical path grows with each additional parallel input. As a result, the encoder operational frequency is decreased quickly. At the same time, increasing communications, storage, and processing demands require ever more efficient error correction.

Consequently, it is desirable to provide improved mechanisms of encoding Reed-Solomon code words. For example, it is desirable to provide a Reed-Solomon encoder that can be easily parallelized and have obvious points of inserting pipelining so that the Reed-Solomon encoder can be used in very fast systems (e.g., 100G Ethernet or 400G Ethernet).

In certain embodiments, Reed-Solomon encoding and/or decoding circuitry may be implemented in an integrated circuit that is coupled to a network, as an example.

It will be recognized by one skilled in the art, that the present exemplary embodiments may be practiced without some or all of these specific details. In other instances, well-known operations have not been described in detail in order not to unnecessarily obscure the present embodiments.

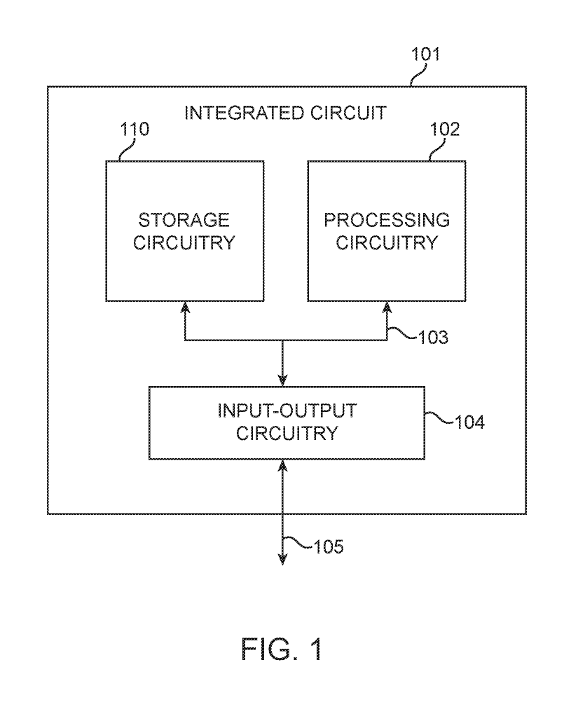

An illustrative embodiment of an integrated circuit 101 is shown in FIG. 1. Integrated circuit 101 may have multiple components. These components may include processing circuitry 102, storage circuitry 110, and input-output circuitry 104. Processing circuitry 102 may include embedded microprocessors, digital signal processors (DSP), microcontrollers, or other processing circuitry.

Storage circuitry 110 may have random-access memory (RAM), read-only memory (ROM), or other addressable memory elements. Storage circuitry 110 may be a single-port memory, a dual-port memory, a quad-port memory, or have any other arbitrary number of ports. If desired, storage circuitry 110 may be implemented as a single-port memory with control circuitry that emulates dual-port, quad-port, or other multi-port behavior. Processing circuitry 102 may access storage circuitry 110 by sending read and/or write requests over interconnection resources 103 to storage circuitry 110. In some embodiments, external components may access storage circuitry 110 via external interconnection resources 105, input-output circuitry 104, and interconnection resources 103. In response to receiving a read request, storage circuitry 110 may retrieve the requested data and send the retrieved data over interconnection resources 103 to the requestor. In case of a write request, storage circuitry 110 may store the received data.

Internal interconnection resources 103 such as conductive lines and busses may be used to send data from one component to another component or to broadcast data from one component to one or more other components. External interconnection resources 105 such as conductive lines and busses, optical interconnect infrastructure, or wired and wireless networks with optional intermediate switches may be used to communicate with other devices.

Input-output circuitry 104 may include parallel input-output circuitry, differential input-output circuitry, serial data transceiver circuitry, or other input-output circuitry suitable to transmit and receive data. If desired, input-output circuitry 104 may include error detection and/or error correction circuitry. For example, input-output circuitry 104 may include Reed-Solomon encoding and/or decoding circuitry that encode data signals by creating Reed-Solomon code words based on the data signals before the data transmission or decode Reed-Solomon code words after the data reception to allow for error correction and reconstitution of the data signals.

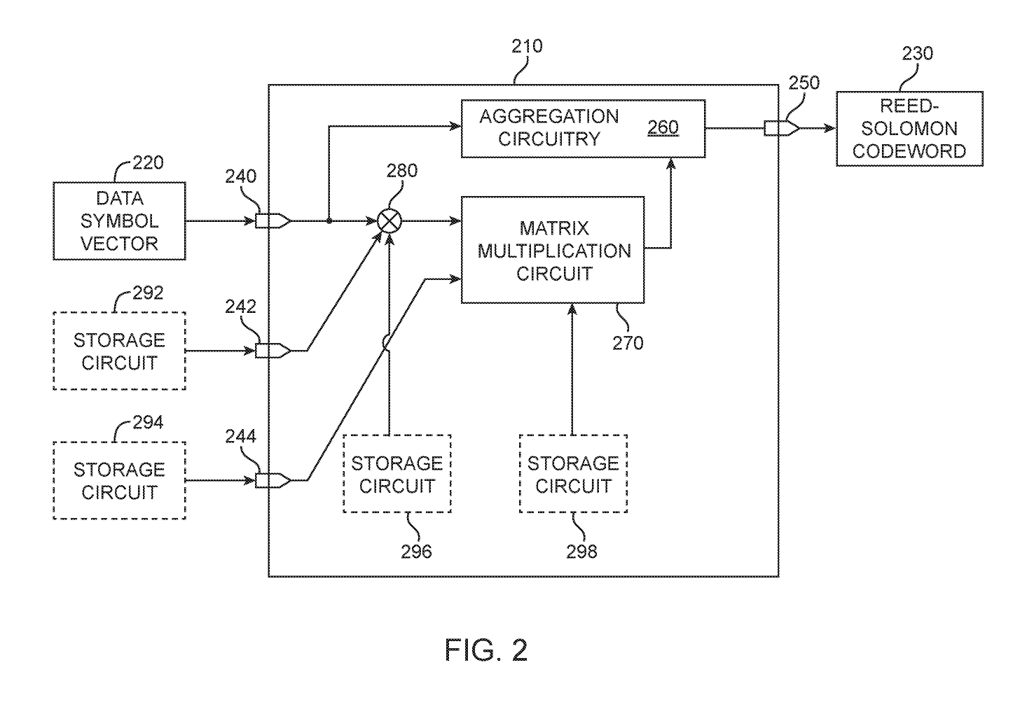

FIG. 2 illustrates such a Reed-Solomon encoder circuit such as encoder 210. As shown in FIG. 2, Reed-Solomon encoder circuit 210 may include input ports 240, 242, and 244, output port 250, multiplier 280, matrix multiplication circuit 270, aggregation circuitry 260, and optional storage circuits 296 and 298.

Reed-Solomon encoder circuit 210 may receive a data symbol vector m (220 in FIG. 2), which is sometimes also referred to as a message, at input port 240 and provide a Reed-Solomon code word c (230 in FIG. 2) at output port 250. As an example, data symbol vector m may have k symbols, and Reed-Solomon code word c may have n symbols, where n>k. The n-symbol Reed-Solomon code word 230 may include 2t=n−k parity check symbols p that allow for the detection of up to 2t erroneous symbols and the correction of up to t symbols. The lower-case notation m, c, and p may be used when referring to the message, code word, and parity symbols, respectively, as vectors. In contrast, the upper-case notation M(X), C(X), and P(X) may be used when treating them as polynomials, where each individual vector element then becomes a polynomial coefficient.

Reed-Solomon encoding operates over a finite field, and the n-symbol Reed-Solomon code word 230 may be defined as:

C(X)=X^{(n-k)}M(X)+P(X) (1)

where X^{(n-k)} shifts data symbol vector m such that the data symbol vector m doesn't overlap with the parity check symbols p.

The Reed-Solomon code word 230 may be transmitted over a connection and received by a Reed-Solomon decoder circuit as a word r that has n symbols. Word r may include error word e in addition to Reed-Solomon code word c (i.e., r=c+e). The Reed-Solomon decoder circuit may check the word r to detect and correct the error with the goal of restoring the message. For example, the Reed-Solomon decoder circuit may compute a syndrome vector syn for the received word using a parity check matrix S, which may have n rows and 2t=(n−k) columns:

syn=r*S=c*S+e*S (2)

Consider the scenario in which the word r is received without an error (i.e., e=0 and r=c). In this scenario, equation 2 is equal to zero (i.e., syn=c*S=0), because S is the parity check matrix of the Reed-Solomon code and the Reed-Solomon code word c evaluated at any root is zero.

Thus, if desired, the Reed-Solomon encoder circuit 210 may use the parity check matrix for the encoding and derive the parity check symbols so that the produced code word is orthogonal to the parity check matrix. In this scenario, the Reed-Solomon encoding problem may be stated as a matrix problem in the form:

m*Sᵤ+p*S_{d}=0 (3)

where m is the k-symbol message, p is the (n−k) parity check symbols, Sᵤ includes the first k rows of S, S_{d} the last (n−k) rows of S. For example, matrices Sᵤ and S_{d} may be defined as:

$$\begin{matrix}{S}_{u} = [ \begin{matrix}{α}^{( n - k - 1 ) ( n - 1 )} & … & {α}^{n - 1} , {α}^{0} \\ ⋮ & ⋱ & ⋮ \\ {α}^{( n - k - 1 ) ( n - k )} & … & {α}^{n - k} , {α}^{0}\end{matrix} ] \\ and & ( 4 ) \\ {S}_{d} = [ \begin{matrix}{α}^{{( n - k - 1 )}^{2}} & … & {α}^{n - k - 1} , {α}^{0} \\ ⋮ & ⋱ & ⋮ \\ {α}^{0} & … & {α}^{0} , {α}^{0}\end{matrix} ] & ( 5 )\end{matrix}$$

Matrices Sᵤ and S_{d} may be computed using the generator polynomial of the finite field, which may be sometimes also referred to as the field polynomial. The field polynomial is usually provided by an industry standard. For example, the 100G Ethernet standard IEEE 802.3bj defines a Reed-Solomon code with n=528, k=514, t=14, and a field polynomial X̂10+X̂3+1.

Thus, all elements in matrices Sᵤ and S_{d} may be computed once. If desired, matrices Sᵤ and S_{d} may be stored in storage circuits. For example, Reed-Solomon encoder circuit 210 may include storage circuits 296 and 298 to store matrices Sᵤ and S_{d}, respectively. If desired, storage circuits 292 and 294 outside Reed-Solomon encoder circuit 210 may store matrices Sᵤ and S_{d}, respectively, and Reed-Solomon encoder circuit 210 may receive the matrices at input ports 242 and 244, respectively. In some scenarios, one matrix of matrices Sᵤ and S_{d} may be stored inside Reed-Solomon encoder circuit 210 and the other matrix may be stored outside Reed-Solomon encoder circuit 210.

Reed-Solomon encoder circuit 210 may receive message m as data symbol vector 220 at input port 240. Multiplier 280 may multiply message m with matrix Sᵤ to determine a partial syndrome vector v (i.e., v=m*Sᵤ). Multiplier 280 can therefore sometimes be referred to as a partial syndrome generator. For example, multiplier 280 may perform a syndrome calculation on the message and continue the syndrome calculation with zeroes inserted where the unknown parity symbols would be. In another example, multiplier 280 may perform a syndrome calculation on the message, stop the syndrome calculation after the last message symbol, and frequency shift the partially computed syndrome in the frequency domain by multiplying the partially computed syndrome with a set of constants.

At this point, a numerical method is introduced to calculate parity check symbols p. This problem can be summarized as a solution of xA=−b, where A is matrix S_{d}, x is the row vector p, and b is the row vector of partial syndromes m*Sᵤ. By inspection, S_{d} is a Vandermonde matrix, which is an invertible matrix. Thus, the parity check symbols p may be computed as follows:

p*S_{d}*S_{d}⁻¹=−m*Sᵤ*S_{d}⁻¹ (6)

Since S_{d}*S_{d}⁻¹ is equal to one, −m is equal to m in any extension of the binary field GF(2) and v is equal to m*Sᵤ, equation 6 simplifies to:

p=v*S_{d}⁻¹ (7)

In accordance with an embodiment, the solution to equation 7 can be found using Lagrangian polynomials. The required vector p corresponds to a certain polynomial P(X):

P(X) [symbol] Σᵢ₌₀^{n-k-1}pᵢXⁱ (8)

where the coefficients {pᵢ} of P(X) are the elements of the vector p. Suitable values for these coefficients can be calculated using Lagrangian interpolation:

P(X)=Σⱼ₌₀^{n-k-1}vⱼLⱼ(X) (9)

### Where:

$${L}_{j} ( X ) = {\prod }_{i = 0 , i \neq j}^{n - k - 1} \frac{X - {α}_{i}}{{α}_{j} - {α}_{i}} \qquad ( 10 )$$

{vⱼ} are the coefficients of the partial syndrome obtained by computing v=m*Sᵤ. In the following we verify that the coefficients {pᵢ} are actually the parity check symbols satisfying equation 7. Note that Lⱼ(α^{j})=1 while Lⱼ(αⁱ)=0 if i≠j. This means that:

P(α^{j})=vⱼ (11)

where equation 11 holds for any j in 0 . . . n−k−1. Combining equation 8 with equation 11 gives:

P(α^{j})=Σᵢ₌₀^{n-k-1}pᵢα^{ji}=vⱼ (12)

However, Σᵢ₌₀^{n-k-1}pᵢα^{ji} is precisely the j^{th} element of the vector p*S_{d}. This means that:

{p*S_{d}}ⱼ=vⱼ (13)

Since equation 13 holds for all j in 0 . . . n−k−1 (i.e. for all rows of the vector), we get:

p*S_{d}=v (14)

Since S_{d} is invertible, we also get:

p=v*S_{d}⁻¹ (15)

as required by equation 7.

As a simple example with (n−k)=3, the polynomial can be expanded as follows:

$$P ( X ) = \frac{( X - α ) ( X - {α}^{2} )}{( 1 - α ) ( 1 - {α}^{2} )} {v}_{0} + \frac{( X - 1 ) ( X - {α}^{2} )}{( α - 1 ) ( α - {α}^{2} )} {v}_{1} + \frac{( X - 1 ) ( X - α )}{( {α}^{2} - α ) ( {α}^{2} - 1 )} {v}_{2} \qquad ( 16 )$$

The coefficients for each vⱼ remains constant (since α is known for a given finite field) and only the syndromes vⱼ will change with each new message.

As another example, consider a scenario in which a Reed-Solomon code word is defined such that n=30, k=24, and m=8, with field polynomial X⁸+X⁴+X³+X²+1. Since (n−k) is equal to six in this example, the corresponding polynomial will have six terms can be expanded as follows:

$$P ( X ) = \frac{( X - α ) ( X - {α}^{2} ) ( X - {α}^{3} ) ( X - {α}^{4} ) ( X - {α}^{5} )}{( 1 - α ) ( 1 - {α}^{2} ) ( 1 - {α}^{3} ) ( 1 - {α}^{4} ) ( 1 - {α}^{5} )} {v}_{0} + \frac{( X - 1 ) ( X - {α}^{2} ) ( X - {α}^{3} ) ( X - {α}^{4} ) ( X - {α}^{5} )}{( α - 1 ) ( α - {α}^{2} ) ( α - {α}^{3} ) ( α - {α}^{4} ) ( α - {α}^{5} )} {v}_{1} + \frac{( X - 1 ) ( X - α ) ( X - {α}^{3} ) ( X - {α}^{4} ) ( X - {α}^{5} )}{( {α}^{2} - 1 ) ( {α}^{2} - α ) ( {α}^{2} - {α}^{3} ) ( {α}^{2} - {α}^{4} ) ( {α}^{2} - {α}^{5} )} {v}_{2} + \frac{( X - 1 ) ( X - α ) ( X - {α}^{2} ) ( X - {α}^{4} ) ( X - {α}^{5} )}{( {α}^{3} - 1 ) ( {α}^{3} - α ) ( {α}^{3} - {α}^{2} ) ( {α}^{3} - {α}^{4} ) ( {α}^{3} - {α}^{5} )} {v}_{3} + \frac{( X - 1 ) ( X - α ) ( X - {α}^{2} ) ( X - {α}^{3} ) ( X - {α}^{5} )}{( {α}^{4} - 1 ) ( {α}^{4} - α ) ( {α}^{4} - {α}^{2} ) ( {α}^{4} - {α}^{3} ) ( {α}^{4} - {α}^{5} )} {v}_{4} + \frac{( X - 1 ) ( X - α ) ( X - {α}^{2} ) ( X - {α}^{3} ) ( X - {α}^{4} )}{( {α}^{5} - 1 ) ( {α}^{5} - α ) ( {α}^{5} - {α}^{2} ) ( {α}^{5} - {α}^{3} ) ( {α}^{5} - {α}^{4} )} {v}_{5} \qquad ( 17 )$$

Now, consider that an illustrative 24 symbol message contains monotonically decreasing values m={30, 29, 28, . . . , 8, 7} and that the partial syndromes m*Sᵤ={115, 192, 21, 217, 192, 24}. In other words, {v₀, v₁, v₂, v₃, v₄, v₅} is equal to {24, 192, 217, 21, 192, 115}, respectively.

The roots of the field 1, α, α², α³, α⁴, and α⁵ can be calculated from the field polynomial, and are equal to 1, 2, 4, 8, 16, and 32, respectively. Substituting these values into equation 17, the denominator of the first term is equal to 6, and the numerator is:

X⁵+62X⁴+63X³+229X²+197X+38 (18)

Thus, the first Lagrange polynomial term (i.e., the coefficient of v₀) is equal to:

122X⁵+254X⁴+132X³+84X²+175X+250 (19)

Similarly, the second to fifth Lagrange polynomial terms can be computed and are equal to:

187X⁵+93X⁴+X³+153X²+209X+175 (20)

46X⁵+108X⁴+131X³+12X²+153X+84 (21)

133X⁵+105X⁴+234X³+131X²+X+132 (22)

60X⁵+154X⁴+105X³+108X²+93X+254 (23)

86X⁵+60X⁴+133X³+46X²+187X+122 (24)

Although equations 19-24 seem fairly complicated, they can all be computed in advance since they are constant for any given code word. As a result, calculation of the parity check symbols now becomes a simple matrix multiplication operation based on the Lagrange polynomial terms and the calculated partial syndromes m*Sᵤ. Substituting the partial syndromes into equation 17, the parity check symbols can be computed as follows:

P(X) [symbol] p₅X⁵+p₄X⁴+p₃X³+P₂X²+p₁X+P₀=(122X⁵+254X⁴+132X³+84X²+175X+250)*24+(187X⁵+93X⁴+X³+153X²+209X+175)*192+(46X⁵+108X⁴+131X³+12X²+153X+84)*217+(133X⁵+105X⁴+234X³+131X²+X+132)*21+(60X⁵+154X⁴+105X³+108X²+93X+254)*192+(86X⁵+60X⁴+133X³+46X²+187X+122)*115 (25)

Where p₅ is equal to the sums of all the X⁵ products, which is equal to 116 (=24*122+192*187+ . . . +115*86, e.g., using Galois field arithmetic). Similarly p₄ is equal to the sums of all the X⁴ products; p₃ is equal to the sums of all the X³ products; etc. As a reminder 24=v₀, 192=v₁, 217=v₃, etc. All remaining parity check symbols can be computed in this way.

Aggregation circuit 260 of FIG. 2 may combine the data symbol vector and the parity check symbols, thereby generating Reed-Solomon code word 230, and provide Reed-Solomon code word 230 at output port 250 of Reed-Solomon encoder circuit 210.

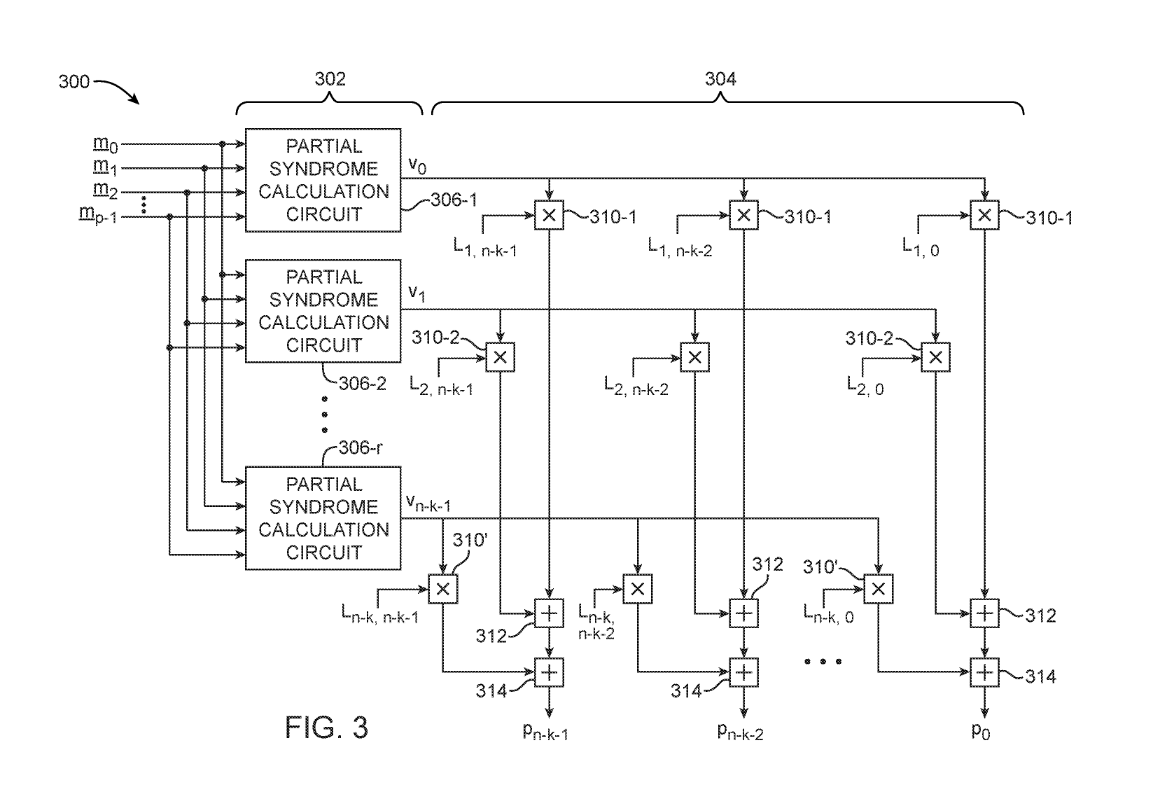

FIG. 3 is a diagram of an illustrative Reed-Solomon encoder circuit such as encoder 300. As shown in FIG. 3, encoder 300 may include: (1) a first stage having partial syndrome calculation circuitry 302 and (2) a second stage having matrix multiplication circuitry 304. In accordance with some embodiments, partial syndrome calculation circuitry 302 may be configured to calculate the partial syndromes in various different ways (e.g., to compute m*Sᵤ).

A first method involves using a decoder style syndrome circuit that can be applied to the message, and then (n−k) zero valued symbols can be input to the syndrome circuit to create shifted syndrome values. This type of syndrome circuit can be efficiently parallelized to process multiple message symbols at a time, as described in U.S. Pat. No. 8,347,192, which is hereby incorporated by reference in its entirety. This method may take advantage of existing syndrome circuitry, but at the cost of (n−k) additional clock cycles.

A second method involves using the syndrome circuit on the message, and then shifting all of the syndromes in a single multiplication step (e.g., using (n−k) Galois Field (“GF( )”) multipliers). This method may require additional logic (although GF( ) multipliers are relatively small), but will save on the order of (n−k) clock cycles.

A third method involves using the syndrome circuit on the message as in the second method, while using an alternate form of the matrix multiplication values. In particular, each Lagrangian polynomial can be multiplied by a respective syndrome shift value. Performing multiplication in this way takes advantage of the fact that the Lagrangian polynomial terms are constants, which can be computed in advance (e.g., the Lagrangian coefficients can be stored as predetermined values).

A fourth method involves performing a direct matrix multiplication of the message m with the syndrome matrix Sᵤ. This method is optimal for very high speed applications, but requires more resources. The various methods described above are merely illustrative and are not intended to limit the scope of the present invention. If desired, other suitable ways for computing the partial syndrome values can be employed.

In the example of FIG. 3, partial syndrome calculation circuitry 302 may include partial syndrome calculation circuits 306-1, 306-2, . . . , and 306-r (where r=n−k). Each of the r partial syndrome calculation circuits 306 may receive p message symbols m₀, m₁, m₂, . . . , mₚ₋₁ in parallel, where p may have a value less than k (e.g., k may be an integer multiple of p). For example, if k is equal to 240 and p is equal to 24, it would take ten clock cycles (240 divided by 24) for partial syndrome calculation circuits 306 of finish computing the partial syndrome values. This implementation is similar to the first method described above. If desired, message symbols may be fed into circuitry 302 via a single wire instead of parallel wires to implement a more iterative approach.

Still referring to FIG. 3, each partial syndrome calculation circuit 306 may output a respective partial syndrome. For example, circuit 306-1 may output first partial syndrome v₀; circuit 306-2 may output second partial syndrome v₁; and circuit 306-r may output (n−k)^{th} partial syndrome vₙ₋ₖ₋₁. After a certain number of clock cycles, circuitry 302 will provide (n−k) partial syndromes at its output.

Matrix multiplication circuitry 304 may receive the partial syndromes generated from circuitry 302 and is configured to calculate all parity (check) symbols simultaneously in one clock cycle. Matrix multiplication circuitry 304 may be effectively configured to perform all the multiplication and addition operations of equation 25. Circuitry 304 may take each of the received partial syndromes v and multiply them by all the terms in each Lagrangian polynomial. Each product can then be summed with all of the other products of the same coefficient index for each polynomial (e.g., all the X⁵ products can be added together to produce parity symbol p₅, all the X⁴ products can be added together to produce p₄, all the X³ products can be added together to produce p₃, etc.).

For example, for parity symbol pₙ₋ₖ₋₁: v₀ is multiplied by the (n−k)^{th} coefficient L_{1,n-k-1} in the first Lagrangian polynomial using constant GF( ) multiplier 310-1; v₁ is multiplied by the (n−k)^{th} coefficient L_{2,n-k-1} in the second Lagrangian polynomial using constant GF( ) multiplier 310-2; and vₙ₋ₖ₋₁ is multiplied by the (n−k)^{th} coefficient L_{n-k,n-k-1} in the last Lagrangian polynomial using constant GF( ) multiplier 310′. In this example, Lagrangian coefficients L_{1,n-k-1}=122, L_{2,n-k-1}=187, and L_{n-k,n-k-1}=86 (see, e.g., equation 25).

Similarly, for parity symbol p₀: v₀ is multiplied by the constant L_{1,0} in the first Lagrangian polynomial using constant GF( ) multiplier 310-1; v₁ is multiplied by constant L_{2,0} in the second Lagrangian polynomial using constant GF( ) multiplier 310-2; and vₙ₋ₖ₋₁ is multiplied by constant L_{n-k,0} in the last Lagrangian polynomial using constant GF( ) multiplier 310′. In this example, Lagrangian constant coefficients L_{1,0}=250, L_{2,0}=175, and L_{n-k,0}=122 (see, e.g., equation 25).

Note that constant GF( ) multipliers 310 can be used since all Lagrangian coefficients are constant and can be precomputed in advance. The predetermined Lagrangian coefficients may be held locally in storage circuits 296 or 298 (see, e.g., FIG. 2). Additional multipliers 310 associated with partial syndromes v₂ through vₙ₋ₖ₋₂ are not shown so as to not unnecessarily obscure the present embodiments. All of the products for each parity symbol are summed together using GF( ) adders 312 and 314. All intermediate parity check symbols p₁ through pₙ₋ₖ₋₂ can also be computed in this way using constant GF( ) multipliers 310 and adders 312/314.

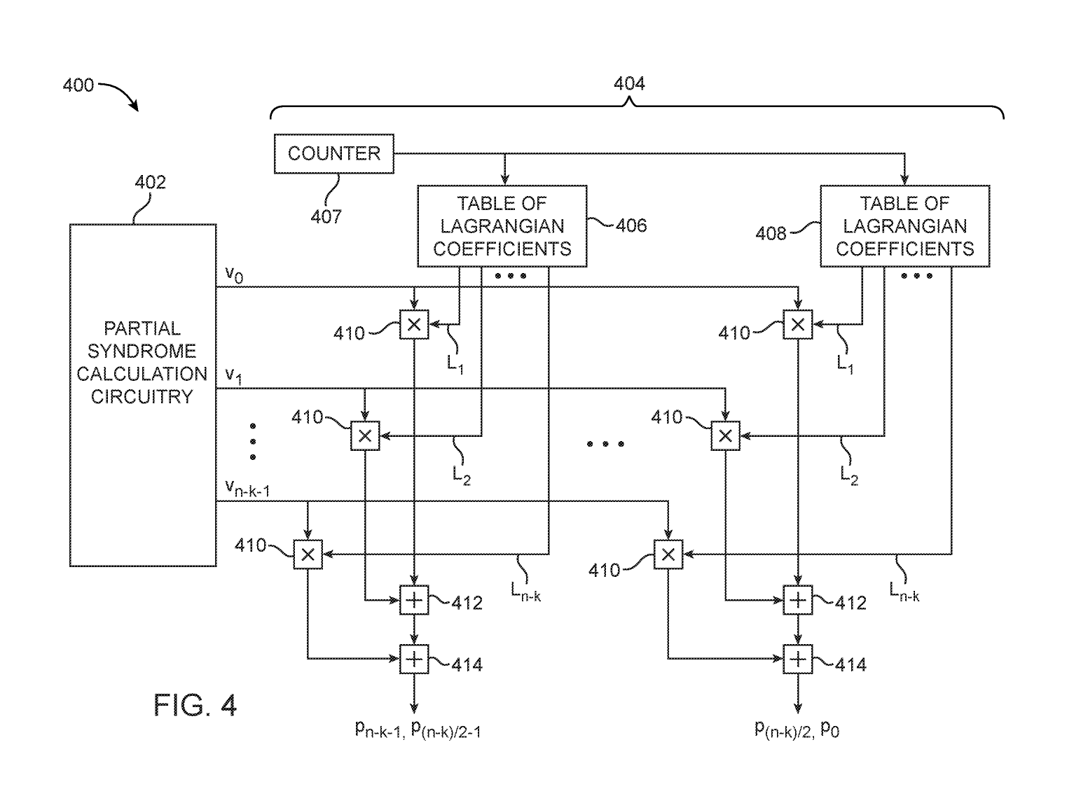

In accordance with another suitable embodiment, FIG. 4 shows a Reed-Solomon encoder circuit such as encoder 400 that generates parity symbols over more than one clock cycle. This may be useful when the parallelism in the partial syndrome generation stage is relatively low. As with the encoder of FIG. 3, encoder 400 of FIG. 4 may include: (1) a first stage having partial syndrome calculation circuitry 402 and (2) a second stage having matrix multiplication circuitry 404. As with circuitry 302, partial syndrome calculation circuitry 402 can also be configured to calculate the partial syndromes in various different ways to produce v₀ through vₙ₋ₖ₋₁ (the details of which is already described above and need not be repeated).

Matrix multiplication circuitry 404 may receive partial syndromes v from partial syndrome calculation circuitry 402 and output corresponding parity symbols over multiple clock cycles. Depending on the parallelism of encoder 404, two or more clock cycles can be required for outputting the parity check symbols. As an example of a Reed-Solomon encoding with n=528, k=514, and parallelism=8, 66 clocks are required for the entire codeword, with the last two clock cycles for outputting the 14 parity check symbols. As another example with n=544, k=514, and parallelism=8, 68 clocks are required for the entire codeword, with the last four clock cycles required outputting the 30 parity check symbols.

In yet other suitable configurations, many more clock cycles can be used to generate the parity symbols. This can be used to create a smaller, longer latency encoder. For example, a Reed-Solomon encoding with n=544, k=514, and parallelism=8, the entire codeword must be transmitted in 68 clock cycles. If the parity generation were to take 30 clock cycles, then the message could be delayed 30 clock cycles before being sent. Even if the parity generation took 60 clock cycle, there would be enough time to output the codeword. The advantage for multi-cycle codeword is resource savings. The single-cycle codeword generation will require (n−k)² GF( ) multipliers. In the scenario where (n−k)=30, 900 GF( ) multipliers would be required.

A two-cycle codeword generation, as shown in the exemplary configuration of FIG. 4, will instead require half the number of multipliers (e.g., only 450 GF( ) multipliers instead of 900). Multipliers 410 of FIG. 4 are, however, variable multipliers (e.g., multipliers that are capable of receiving varying input values, not just constant values), which may be larger than the constant multipliers 310 of FIG. 3. In general, constant multipliers might be at least two or four times smaller than variable multipliers. In the example above where (n−k)=30, a 30-cycle parity generation would require only 30 variable multipliers, which would be much smaller than 900 constant multipliers.

Referring specifically to FIG. 4, encoder 400 embodies a two-cycle parity generation scheme. In the first cycle, counter 407 may provide a first address value to both tables 406 and 408 to output the highest indexed coefficients of each Lagrangian polynomial, which are all provided in parallel to each GF( ) multiplier 410. Tables 406 and 408 are configured to store predetermined Lagrangian coefficients L₁ through Lₙ₋ₖ, which are different for each parity symbol and changes from cycle to cycle (e.g., tables 406 and 408 are used to store the coefficients in equation 25). The different products associated with each parity symbol can be summed together using GF( ) adders such as adders 412 and 414. There may be (n−k)/2 multipliers 410 for each of the (n−k) syndromes, generating the highest indexed parity symbols from Pₙ₋ₖ₋₁ down to P_{(n-k)/2} during the first cycle.

In the second cycle, counter 407 may provide a second address value to both tables 406 and 408 to output the lowest indexed coefficients of each Lagrangian polynomial, which are all provided in parallel to each GF( ) multiplier 410. The different products associated with each parity symbol can be summed together using GF( ) adders such as adders 412 and 414. The (n−k)/2 multipliers 410 for each of the (n−k) syndromes can then be used to generate the lowest indexed parity symbols from P_{(n-k)/2} down to P₀ during the second cycle.

The configuration of FIG. 4 in which the matrix multiplication is performed within two clock cycles is merely illustrative. If desired, encoder 400 may be configured to perform matrix multiplication in more than two cycles, in eight or more clock cycles, in ten or more clock cycles, etc. In the case where the matrix multiplication is performed in eight clock cycles, counter may be configured to count from 0-7, resetting at a count of 7. In the case where the matrix multiplication is performed in ten clock cycles, counter may be configured to count from 0-9, resetting at a count of 9.

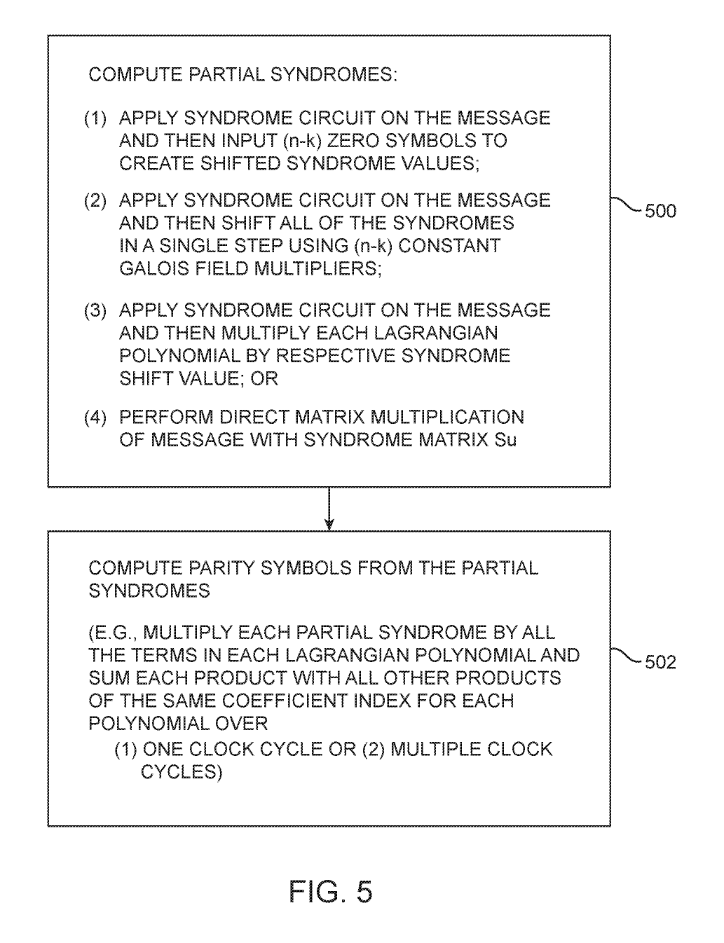

FIG. 5 is a flow chart of illustrative steps for operating a matrix multiplication based Reed-Solomon encoder circuit of the type shown in connection with FIGS. 2-4. At step 500, partial syndrome calculation circuitry 302 of FIG. 3 or circuitry 402 of FIG. 4 may be used to compute the (n−k) partial syndromes v. The partial syndrome values may be computed via at least four different ways, such as by: (1) applying the syndrome circuit on the message and then inputting (n−k) zero symbols to create shifted syndrome values, (2) applying the syndrome circuit on the message and then shifting all of the syndromes in a single step using (n−k) constant GF( ) multipliers, (3) applying the syndrome circuit on the message and then multiplying each Lagrangian polynomial by a respective syndrome shift value, or (4) performing a direct matrix multiplication of the message with syndrome matrix Sᵤ.

At step 502, matrix multiplication circuitry may be used to compute parity check symbols based on the partial syndromes generated during step 500 and based on predetermined Lagrangian coefficients. In one suitable arrangement, matrix multiplication circuitry 304 of FIG. 3 may be configured to multiply each partial syndrome by all the terms in each Lagrangian polynomial and sum each product with all other products of the same coefficient index for each parity check symbol over one clock cycle. In another suitable arrangement, matrix multiplication circuitry 404 of FIG. 4 may be configured to multiply each partial syndrome by all the terms in each Lagrangian polynomial and sum up each product with all other products of the same coefficient index for a portion of the parity check symbols per clock cycle over a number of clock cycles.

The steps of FIG. 5 for computing parity check symbols using matrix multiplication are merely illustrative. In general, the parity symbols may be computed within any suitable number of clock cycles, using constant or variable Galois Field multipliers to multiply the partial syndromes by precomputed Lagrangian coefficients and using Galois Field adders to sum up product terms associated with the same parity index. Computing parity check symbols in this way enables designers to build the Reed-Solomon encoders with a smaller, faster core, with much lower logic depth (i.e., much less pipelining is needed).

The foregoing is merely illustrative of the principles of this invention and various modifications can be made by those skilled in the art. The foregoing embodiments may be implemented individually or in any combination.

What is claimed is:

1. An integrated circuit, comprising:
partial syndrome calculation circuitry that receives a message and that generates corresponding partial syndrome values; and
matrix multiplication circuitry that receives the partial syndrome values from the partial syndrome calculation circuitry and that generates corresponding parity symbols.

2. The integrated circuit of claim 1, wherein the matrix multiplication circuitry includes an array of Galois Field multipliers.

3. The integrated circuit of claim 2, wherein the array of Galois Field multipliers comprises constant Galois Field multipliers, each of which receives a respective precomputed Lagrangian coefficient.

4. The integrated circuit of claim 2, wherein the array of Galois Field multipliers comprises variable Galois Field multipliers, each of which receives varying Lagrangian coefficients.

5. The integrated circuit of claim 2, wherein the matrix multiplication circuitry includes Galois Field adders for summing products generated from the array of Galois Field multipliers.

6. The integrated circuit of claim 1, wherein the partial syndrome calculation circuitry includes a plurality of partial syndrome calculation circuits, each of which receives the same message symbols in parallel.

7. The integrated circuit of claim 4, wherein the matrix multiplication circuitry further includes:
a plurality of tables that store the Lagrangian coefficients; and
a counter that addresses the plurality of tables.

8. The integrated circuit of claim 1, wherein the matrix multiplication circuitry is configured to generate the parity symbols in a single clock cycle.

9. The integrated circuit of claim 1, wherein the matrix multiplication circuitry is configured to generate the parity symbols over multiple clock cycles.

10. A method for operating an integrated circuit, comprising:
with partial syndrome calculation circuitry in the integrated circuit, receiving a message and generating partial syndromes; and
with matrix multiplication circuitry in the integrated circuit, receiving the partial syndromes from the partial syndrome calculation circuitry and generating parity check symbols.

11. The method of claim 10, wherein generating the parity check symbols comprises generating all of the parity check symbols in only one clock cycle.

12. The method of claim 10, wherein generating the parity check symbols comprises generating a first portion of the parity check symbols in a first clock cycle and generating a second portion of the parity check symbols in a second clock cycle immediately following the first clock cycle.

13. The method of claim 10, wherein generating the partial syndromes comprises shifting in zero value symbols to create shifted syndrome values.

14. The method of claim 10, wherein generating the partial syndromes comprises shifting the partial syndromes in a single step using a plurality of constant Galois Field multipliers.

15. The method of claim 10, wherein generating the partial syndromes comprises multiplying a Lagrangian polynomial by a syndrome shift value.

16. The method of claim 10, wherein generating the partial syndromes comprises multiplying the message by a syndrome matrix.

17. A Reed-Solomon encoder circuit, comprising:
partial syndrome calculation circuitry that receives a message and that outputs partial syndromes;
a first set of multipliers that multiplies the partial syndromes by a first set of Lagrangian coefficients to output a first set of products;
a second set of multipliers that multiplies the partial syndromes by a second set of Lagrangian coefficients to output a second set of products;
a first set of adders for summing the first set of products to output a first parity check symbol; and
a second set of adders for summing the second set of products to output a second parity check symbol.

18. The Reed-Solomon encoder circuit of claim 17, wherein the first and second set of multipliers comprises multipliers selected from the group consisting of: constant Galois Field multipliers and variable Galois Field multipliers.

19. The Reed-Solomon encoder circuit of claim 17, wherein the first and second Lagrangian coefficients comprise precomputed constants held in storage circuits.

20. The Reed-Solomon encoder circuit of claim 17, wherein the first set of adders outputs the first parity check symbol associated with the received message during a first clock cycle and further outputs a third parity check symbol that is different than the first parity check symbol and that is also associated with the received message during a second clock cycle immediately following the first clock cycle.
